(19) United States
(12) Patent Application Publication
(10) Pub. No.: US 2026/0090220 A1
(43) Pub. Date: Mar. 26, 2026

(54) THIN FILM TRANSISTOR SUBSTRATE AND DISPLAY DEVICE COMPRISING THE SAME

(71) Applicant: LG Display Co., Ltd., Seoul (KR)

(72) Inventors: Youngjin Yi, Paju-si (KR); Sohyung Lee, Paju-si (KR); Hyelim Ji, Paju-si (KR); Soyang Choi, Paju-si (KR)

(73) Assignee: LG Display Co., Ltd., Seoul (KR)

(21) Appl. No.: 19/241,698

(22) Filed: Jun. 18, 2025

(30) Foreign Application Priority Data
Sep. 23, 2024 (KR) 10-2024-0128375

(51) Int. Cl. H10K 59/126; G09G 3/3233; G09G 3/3266

(52) U.S. Cl. CPC H10K 59/126; G09G 3/3233; G09G 3/3266; G09G 2300/0426; G09G 2300/0842; G09G 2320/0233

(57) ABSTRACT

A thin film transistor substrate including a first switching thin film transistor on a base substrate; and a second driving thin film transistor on the base substrate and spaced apart from the first switching thin film transistor. Further, the first switching thin film transistor includes a first active layer; a first gate electrode at least partially overlapping the first active layer; and a first light-blocking layer disposed between the base substrate and the first active layer and overlapping the first active layer. In addition, the second driving thin film transistor includes a second active layer; a second gate electrode at least partially overlapping the second active layer; and a second light-blocking layer disposed between the base substrate and the second active layer and overlapping the second active layer. Also, the first light-blocking layer and the second light-blocking layer are made of different materials, and a hydrogen concentration of the second active layer is higher than a hydrogen concentration of the first active layer.

### CROSS-REFERENCE TO RELATED APPLICATIONS

This application claims priority to Korean Patent Application No. 10-2024-0128375, filed in the Republic of Korea on September 23, 2024, the entire contents of which is hereby expressly incorporated by reference into the present application.

### BACKGROUND

### Field of the Invention

The present disclosure relates to an apparatus and more particularly to a thin film transistor substrate and a display device including the thin film transistor substrate.

### Discussion of the Related Art

Transistors are widely used as switching devices or driving devices in the field of electronic devices. In particular, thin film transistors are widely used as switching devices in display devices such as liquid crystal display devices or organic light emitting devices because they can be manufactured on glass or plastic substrates. However, the switching thin film transistor and the driving thin film transistor have different optimal characteristics.

### SUMMARY

Accordingly, an object of the present disclosure is to overcome the differences in device characteristics between switching thin film transistors and driving thin film transistors.

Another object of the present disclosure is to provide a thin film transistor substrate having improved characteristics of a first thin film transistor and a second thin film transistor by having different light-blocking layers.

Yet another object of the present disclosure is to provide a thin film transistor substrate in which the hydrogen concentration of each active layer of a first thin film transistor and a second thin film transistor is controlled by having different light-blocking layers.

Still another object of the present disclosure is to provide a thin film transistor substrate in which threshold voltages of a first thin film transistor and a second thin film transistor are controlled by having different light-blocking layers.

To achieve these and other advantages and in accordance with the purpose of the present disclosure, as embodied and broadly described herein, the present disclosure provides in one aspect a thin film transistor substrate including a first thin film transistor on a base substrate; and a second thin film transistor spaced apart from the first thin film transistor, wherein the first thin film transistor includes a first active layer; a first gate electrode at least partially overlapping the first active layer; and a first light-blocking layer disposed between the base substrate and the first active layer and overlapping the first active layer, and the second thin film transistor includes a second active layer; a second gate electrode at least partially overlapping the second active layer; and a second light-blocking layer disposed between the base substrate and the second active layer and overlapping the second active layer. Further, the first light-blocking layer and the second light-blocking layer are made of different materials, and a hydrogen concentration (at %) of the second active layer is higher than a hydrogen concentration (at %) of the first active layer.

In addition, the first active layer can have a hydrogen concentration greater than or equal to 1x10¹⁰ and less than 1x10¹⁷ atomic % (at %) based on the entirety of the first active layer, and the second active layer can have a hydrogen concentration of 1x10¹⁷ to 1x10²¹ atomic % (at %) based on the entirety of the second active layer. The carrier mobility of the second active layer can also be greater than the carrier mobility of the first active layer, and the threshold voltage of the first thin film transistor can be greater than the threshold voltage of the second thin film transistor.

Also, the first light-blocking layer includes a first metal material, the second light-blocking layer includes a second metal material, and the binding energy of the first metal material with hydrogen can be greater than the binding energy of the second metal material with hydrogen. The first metal material may include one of titanium (Ti), molybdenum titanium alloy (MoTi), lithium (Li), hafnium (Hf), lutetium (Lu), tantalum (Ta), magnesium (Mg), vanadium (V), rubinium (Rb), scandium (Sc), strontium (Sr), yttrium (Y), zirconium (Zr), niobium (Nb), cesium (Cs), barium (Ba), and lanthanum (La), and the second metal material may include one of molybdenum (Mo), copper (Cu), tungsten (W), cobalt (Co), zinc (Zn), gallium (Ga), silver (Ag), cadmium (Cd), indium (In), tin (Sn), iridium (Ir), platinum (Pt), and gold (Au).

In addition, the first active layer can be disposed between the first light-blocking layer and the first gate electrode, and the second active layer can be disposed between the second light-blocking layer and the second gate electrode. The first gate electrode can be disposed between the first light-blocking layer and the first active layer, and the second gate electrode can be disposed between the second light-blocking layer and the second active layer.

Another embodiment of the present disclosure provides a thin film transistor substrate including a first thin film transistor on a base substrate; and a second thin film transistor spaced apart from the first thin film transistor. Further, the first thin film transistor comprises: a first active layer; and a first gate electrode disposed between the base substrate and the first active layer and at least partially overlapping the first active layer. In addition, the second thin film transistor includes a second active layer; and a second gate electrode disposed between the base substrate and the second active layer and at least partially overlapping the second active layer. Also, the first gate electrode and the second gate electrode are made of different materials, and a hydrogen concentration (at %) of the second active layer is higher than a hydrogen concentration (at %) of the first active layer. The first gate electrode includes a first metal material, the second gate electrode includes a second metal material, and the binding energy of the first metal material with hydrogen can be greater than the binding energy of the second metal material with hydrogen.

Another embodiment of the present disclosure provides a thin film transistor substrate including a third thin film transistor on a base substrate; and a fourth thin film transistor spaced apart from the third thin film transistor, where the third thin film transistor includes a first active layer; a first gate electrode at least partially overlapping the first active layer; and a first light-blocking layer disposed between the base substrate and the first active layer and overlapping the first active layer. Also, the fourth thin film transistor includes a second active layer; a second gate electrode at least partially overlapping the second active layer; and a second light-blocking layer disposed between the base substrate and the second active layer and overlapping the second active layer. Further, the first active layer comprises a first oxide semiconductor material, the second active layer comprises a second oxide semiconductor material, and a carrier mobility of the first oxide semiconductor material is greater than a carrier mobility of the second oxide semiconductor material, and a thickness of the first light-blocking layer is greater than a thickness of the second light-blocking layer.

The first active layer can have a hydrogen concentration greater than or equal to 1x10¹⁰ and less than 1x10¹⁷ atomic % (at %) based on the entirety of the first active layer, and the second active layer can have a hydrogen concentration greater than or equal to 1x10¹⁰ and less than 1x10¹⁷ atomic % (at %) based on the entirety of the second active layer. The first light-blocking layer and the second light-blocking layer each include a first metal material, and the first metal material may include any one of titanium (Ti), a molybdenum titanium alloy (MoTi), lithium (Li), hafnium (Hf), lutetium (Lu), tantalum (Ta), magnesium (Mg), vanadium (V), rubinium (Rb), scandium (Sc), strontium (Sr), yttrium (Y), zirconium (Zr), niobium (Nb), cesium (Cs), barium (Ba), and lanthanum (La).

Another embodiment of the present disclosure provides a display device including the thin film transistor substrate. The display device includes a gate driver and a pixel driving circuit on the base substrate, the first thin film transistor can be included in the gate driver or can be a switching thin film transistor of the pixel driving circuit, and the second thin film transistor can be a driving thin film transistor of the pixel driving circuit.

The display device also includes a gate driver and a pixel driving circuit on the base substrate, and the first thin film transistor and the second thin film transistor can be included in the gate driver or can be switching thin film transistors of the pixel driving circuit.

Further scope of applicability of the present invention will become apparent from the detailed description given hereinafter. However, the detailed description and specific examples, while indicating preferred embodiments of the invention, are given by illustration only, since various changes and modifications within the spirit and scope of the invention will become apparent to those skilled in the art from this detailed description.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a cross-sectional view of a thin film transistor substrate according to one embodiment of the present disclosure.

FIG. 2 is a cross-sectional view of a thin film transistor substrate according to another embodiment of the present disclosure.

FIG. 3 is a cross-sectional view of a thin film transistor substrate according to another embodiment of the present disclosure.

FIG. 4 is a cross-sectional view of a thin film transistor substrate according to another embodiment of the present disclosure.

FIG. 5 is a schematic diagram of a display device according to one embodiment of the present disclosure.

FIG. 6 is a circuit diagram for one pixel of FIG. 5.

FIG. 7 is a plan view of the pixels of FIG. 6.

FIG. 8 is a cross-sectional view taken along line I-I’ of FIG. 7.

### DETAILED DESCRIPTION OF THE DISCLOSURE

Advantages and features of the present disclosure and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted or can be briefly provided.

In a case where ‘comprise’, ‘have’ and ‘include’ described in the present disclosure are used, another portion can be added unless ‘only~’ is used. The terms of a singular form can include plural forms unless referred to the contrary. In construing an element, the element is construed as including an error band although there is no explicit description. In addition, when any dimensions, relative sizes etc. are mentioned, it should be considered that numerical values for an elements or features, or corresponding information e.g., level, range, etc. include a tolerance or error range that can be caused by various factors e.g., process factors, internal or external impact, noise, etc. even when a relevant description is not specified. Further, the term “can” fully encompasses all the meanings of the term “can.”

Any implementation described herein as an “example” is not necessarily to be construed as preferred or advantageous over other implementations. In describing a position relationship, for example, when the position relationship is described as ‘upon~’, ‘above~’, ‘below~’ and ‘next to~’, one or more portions can be disposed between two other portions unless ‘just’ or ‘direct’ is used.

Spatially relative terms such as "below", “beneath”, “lower”, “above”, and “upper” can be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below”, or “beneath” another device can be arranged “above” another device. Therefore, an exemplary term “below or beneath” can include “below or beneath” and “above” orientations. Likewise, an exemplary term “above” or “on” can include “above” and “below or beneath” orientations.

In describing a temporal relationship, for example, when the temporal order is described as “after,” “subsequent,” “next,” and “before,” a case which is not continuous can be included, unless “just” or “direct” is used. It will be understood that, although the terms “first,” “second,” etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” can include all combinations of two or more elements selected from the first, second and third elements as well as each element of the first, second and third elements. The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

Features of various embodiments of the present disclosure can be partially or overall coupled to or combined with each other and can be variously inter-operated with each other and driven technically as those skilled in the art can sufficiently understand. The embodiments of the present disclosure can be performed independently from each other or can be performed together in a co-dependent relationship. In the addition of reference numerals to the components of each drawing describing embodiments of the present disclosure, the same components can have the same sign as can be displayed on the other drawings.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

Rather, these embodiments can be provided so that this disclosure can be sufficiently thorough and complete to assist those skilled in the art to fully understand the scope of the present disclosure. In the embodiments of the present disclosure, a source electrode and a drain electrode are distinguished for convenience of description, and the source electrode and the drain electrode can be interchanged. The source electrode can be the drain electrode and vice versa. In addition, the source electrode of any one embodiment can be a drain electrode in another embodiment, and the drain electrode of any one embodiment can be a source electrode in another embodiment.

In some embodiments of the present disclosure, for convenience of description, a source area is distinguished from a source electrode, and a drain area is distinguished from a drain electrode, but embodiments of the present disclosure are not limited thereto. The source area can be the source electrode, and the drain area can be the drain electrode. In addition, the source area can be the drain electrode, and the drain area can be the source electrode.

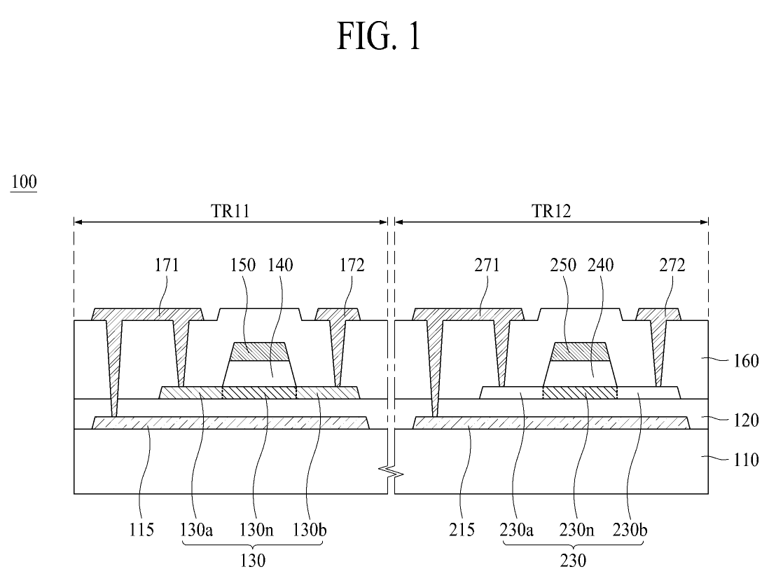

FIG. 1 is a cross-sectional view of a thin film transistor substrate 100 according to one embodiment of the present disclosure. Referring to FIG. 1, the thin film transistor substrate 100 includes a first thin film transistor TR11 and a second thin film transistor TR12 spaced apart from each other.

Referring to FIG. 1, the first thin film transistor TR11 includes a first active layer 130, a first gate electrode 150 that at least partially overlaps the first active layer 130, and a first light-blocking layer 115 disposed between a base substrate 110 and the first active layer 130 and overlapping the first active layer 130. Also, the second thin film transistor TR12 includes a second active layer 230, a second gate electrode 250 that at least partially overlaps the second active layer 230, and a second light-blocking layer 215 disposed between the base substrate 110 and the second active layer 230 and overlapping the second active layer 230.

Hereinafter, components of the thin film transistor substrate 100 according to one embodiment of the present disclosure will be described in more detail.

In particular, the base substrate 110 can be made of glass or plastic, and a transparent plastic having flexible properties, such as polyimide, can be used. When polyimide is used as the base substrate 110, considering that a high-temperature deposition process is performed on the base substrate 110, a heat-resistant polyimide that can withstand high temperatures can be used. In this instance, for forming a thin film transistor, processes such as deposition and etching can be performed while the polyimide substrate is disposed on a carrier substrate made of a highly durable material such as glass.

Referring to FIG. 1, the first light-blocking layer 115 and the second light-blocking layer 215 can be disposed on the base substrate 110. As shown, the first light-blocking layer 115 and the second light-blocking layer 215 can be disposed between the base substrate 110 and the buffer layer 120. In addition, the first light-blocking layer 115 and the second light-blocking layer 215 overlap with the first active layer 130 and the second active layer 230, respectively. Specifically, the first light-blocking layer 115 and the second light-blocking layer 215 can overlap with channel sections 130n, 230n. Also, the first light-blocking layer 115 and the second light-blocking layer 215 block light incident from the outside, thereby protecting the channel section 130n, 230n.

In addition, the first light-blocking layer 115 and second light-blocking layer 215 are made of different materials. Specifically, the first light-blocking layer 115 includes a first metal material, and the second light-blocking layer 215 includes a second metal material. More specifically, the first metal material can be a metal material that captures hydrogen (H), and the second metal material can be a metal material that does not capture or emits hydrogen (H). That is, the first metal material can be more stably bonded to hydrogen than the second metal material. For example, the second metal material can have empty spaces between atoms. In a high-temperature environment, the second metal material can include hydrogen existing in the empty spaces between atoms. Further, when the temperature decreases, hydrogen existing in the second metal material can be emitted to the outside.

In more detail, the first metal material may include any one of titanium (Ti), molybdenum titanium alloy (MoTi), lithium (Li), hafnium (Hf), lutetium (Lu), tantalum (Ta), magnesium (Mg), vanadium (V), rubinium (Rb), scandium (Sc), strontium (Sr), yttrium (Y), zirconium (Zr), niobium (Nb), cesium (Cs), barium (Ba), and lanthanum (La). The second metal material may include any one of molybdenum (Mo), copper (Cu), tungsten (W), cobalt (Co), zinc (Zn), gallium (Ga), silver (Ag), cadmium (Cd), indium (In), tin (Sn), iridium (Ir), platinum (Pt), and gold (Au).

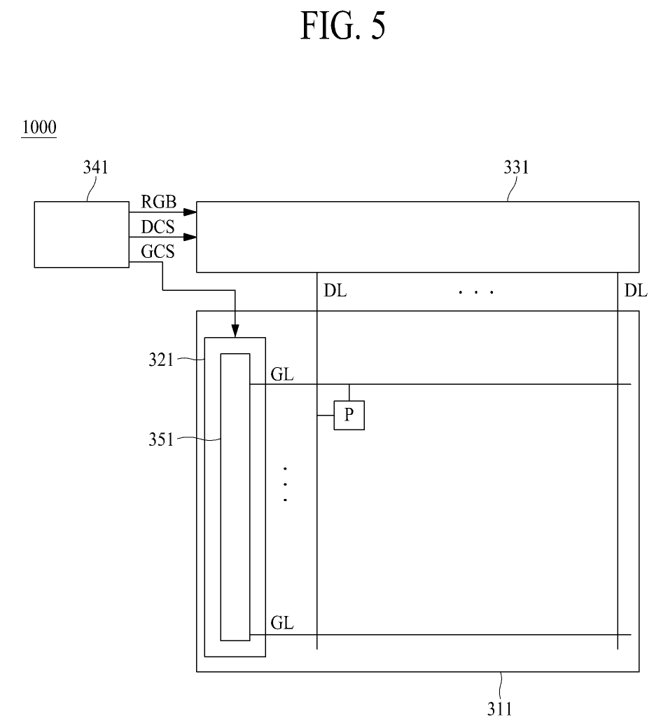

In general, switching thin film transistors and driving thin film transistors have differences in their characteristics between devices. For example, when the width of the bezel increases, there is a problem that the manufacturing cost of the display device increases. Considering this problem, it is preferable to implement a short channel when the switching thin film transistor is included in the gate driver 321 (see FIG. 5). In addition, in order to increase the current capacity in the channel of the switching thin film transistor, the switching thin film transistor implements a short channel.

In addition, for the driving thin film transistor, the dispersion of the threshold voltage is preferably reduced for driving stability. For example, if the dispersion of the threshold voltage of the driving thin film transistor increases, it is difficult to maintain the threshold voltage of the driving thin film transistor constant. As a result, the reliability of the driving thin film transistor deteriorates, causing a problem of lowering the brightness uniformity of the display.

Therefore, the switching thin film transistor preferably implements a short channel and the driving thin film transistor preferably implements an improved driving stability. Further, by controlling the hydrogen capture performance of the light-blocking layers of the switching thin film transistor and the driving thin film transistor, the desired device characteristics of each of the switching thin film transistor and the driving thin film transistor can be improved simultaneously in one panel. Specifically, by capturing hydrogen flowing into the switching thin film transistor, the switching thin film transistor can implement a short channel, and by not capturing hydrogen flowing into the driving thin film transistor, the driving stability of the driving thin film transistor can be improved.

Thus, the thin film transistor substrate 100 according to one embodiment of the present disclosure includes the first thin film transistor TR11 including the first light-blocking layer 115 and the second thin film transistor TR12 including the second light-blocking layer 215. In this instance, the first thin film transistor TR11 can be included in a gate driver 321 or a switching thin film transistor, and the second thin film transistor TR12 can be a driving thin film transistor of a pixel driving circuit PDC.

Specifically, the first light-blocking layer 115 of the first thin film transistor TR11 is made of a material that stably bonds with hydrogen compared to the second light-blocking layer 215 of the second thin film transistor TR12. For example, the first light-blocking layer 115 can be made of a material that has a higher bonding energy with hydrogen compared to the second light-blocking layer 215.

If the first light-blocking layer 115 of the first thin film transistor TR11, which is a switching thin film transistor, is made of a metal material that does not stably bond with hydrogen, for example, if the first light-blocking layer 115 is made of a second metal material, hydrogen (H) diffuses into the first thin film transistor TR11. As a result, hydrogen can penetrate into the channel portion 130n of the first active layer 130, causing the threshold voltage (Vth) of the first thin film transistor TR11 to shift in the negative (-) direction, and it can become difficult for the first thin film transistor TR11 to implement a short channel.

Accordingly, because the first light-blocking layer 115 is made of a first metal material that stably binds to hydrogen, hydrogen (H) can be effectively blocked. As a result, the channel portion 130n of the first active layer 130 can be efficiently protected, and the first thin film transistor TR11 can implement a short channel.

Also, if the second light-blocking layer 215 of the second thin film transistor TR12, which is a driving thin film transistor, is made of a metal material that stably bonds with hydrogen, for example, if the second light-blocking layer 215 is made of the first metal material, hydrogen (H) hardly diffuses into the second thin film transistor TR12. As a result, a positive (+) shift can occur in the threshold voltage (Vth) of the second thin film transistor TR12. As a result, the reliability of the driving thin film transistor is lowered, which causes a problem of lowering the brightness uniformity of the display.

Accordingly, because the second light-blocking layer 215 is made of a second metal material that emits hydrogen (and does not capture hydrogen), the positive (+) shift of the threshold voltage (Vth) of the second thin film transistor TR12 can be suppressed. As a result, the driving stability of the second thin film transistor TR12 can be improved.

According to one embodiment of the present disclosure, the threshold voltage (Vth) of the first thin film transistor TR11 can be greater than the threshold voltage (Vth) of the second thin film transistor TR12. Also, the hydrogen concentration (at %) of the second active layer 230 can be higher than the hydrogen concentration of the first active layer 130.

For example, the first active layer 130 can have a hydrogen concentration greater than or equal to 1x10¹⁰ and less than 1x10¹⁷ atomic % (at %) based on the entirety of the first active layer 130, and the second active layer 230 can have a hydrogen concentration of 1x10¹⁷ to 1x10²¹ atomic % (at %) based on the entirety of the second active layer 230. According to one embodiment of the present disclosure, the carrier mobility of the second active layer 230 can be greater than the carrier mobility of the first active layer 130.

Referring to FIG. 1, a buffer layer 120 can be disposed on the first light-blocking layer 115 and the second light-blocking layer 215. Specifically, the buffer layer 120 can be disposed over the entirety of the first thin film transistor TR11 and the second thin film transistor TR12. The buffer layer 120 is also formed on the base substrate 110 and can include an inorganic material or an organic material. For example, the buffer layer 120 can include an insulating oxide such as silicon oxide (SiOx) or aluminum oxide (Al2O3).

Also, the buffer layer 120 protects the first active layer 130 and the second active layer 230 by blocking impurities such as moisture and oxygen flowing in from the base substrate 110 and serves to flatten the upper portion of the base substrate 110, and can be formed as a single layer or multiple layers. When the buffer layer 120 has multiple layers, each of the multiple layers can be formed of different materials.

Referring again to FIG. 1, the first active layer 130 and the second active layer 230 can be disposed on the buffer layer 120. Also, the first thin film transistor TR11 includes the first active layer 130 on the buffer layer 120, and the second thin film transistor TR12 includes the second active layer 230. As shown in FIG. 1, the first active layer 130 and the second active layer 230 are disposed spaced apart from each other.

In addition, the first active layer 130 and the second active layer 230 can each include the channel portion 130n, 230n, a first connection portion 130a, 230a, and a second connection portion 130b, 230b. Specifically, the first active layer 130 can include the channel portion 130n that overlaps the first gate electrode 150 in a plane view, the first connection portion 130a that does not overlap the first gate electrode 150 in a plane view and is connected to one side of the channel portion 130n, and the second connection portion 130b that does not overlap the first gate electrode 150 in a plane view and is connected to the other side of the channel portion 130n.

In addition, the second active layer 230 can include the channel portion 230n that overlaps the second gate electrode 250 in a plane view, the first connection portion 230a that does not overlap the second gate electrode 250 in a plane view and is connected to one side of the channel portion 230n, and the second connection portion 230b that does not overlap the second gate electrode 250 in a plane view and is connected to the other side of the channel portion 230n.

According to one embodiment of the present disclosure, the first connecting portion 130a, 230a and the second connecting portion 130b, 230b are spaced apart from each other with the channel portion 130n, 230n therebetween. Also, the first active layer 130 and the second active layer 230 can be formed of a semiconductor material and include an oxide semiconductor material.

Further, the oxide semiconductor material can include, for example, at least one of an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, an ITZO (InSnZnO)-based oxide semiconductor material, and a FIZO (FeInZnO)-based oxide semiconductor material. However, the embodiment of the present disclosure is not limited thereto, and the first active layer 130 and the second active layer 230 can be formed of other oxide semiconductor materials.

Also, the first connecting portion 130a, 230a and the second connecting portion 130b, 230b can be formed by selectively conductorization for the first active layer 130 and the second active layer 230 made of a semiconductor material. According to one embodiment of the present disclosure, selectively conductorization refers to imparting conductivity to specific portions of the first active layer 130 and the second active layer 230 so that they can function like conductors.

For example, the first active layer 130 and the second active layer 230 can be selectively made conductorized by ion doping. As a result, the first connecting portion 130a, 230a and the second connecting portion 130b, 230b can be formed. However, the first active layer 130 and the second active layer 230 can also be selectively made conductorized by other methods.

In addition, the first connecting portion 130a, 230a and the second connecting portion 130b, 230b do not overlap with the first gate electrode 150 and the second gate electrode 250. Also, the first connecting portion 130a, 230a and the second connecting portion 130b, 230b have superior electrical conductivity and high mobility compared to the channel portion 130n, 230n. Therefore, the first connecting portion 130a, 230a and the second connecting portion 130b, 230b can each function as a wiring.

According to one embodiment of the present disclosure, the first active layer 130 and the second active layer 230 can have a multilayer structure. Further, the first active layer 130 and the second active layer 230 can also include the same or similar semiconductor material, or can include different semiconductor materials.

The first thin film transistor TR11 can further include a gate insulating film 140 disposed between the first active layer 130 and the first gate electrode 150. Also, the second thin film transistor TR12 can further include a gate insulating film 240 disposed between the second active layer 230 and the second gate electrode 250. Specifically, the first connecting portions 130a, 230a and the second connecting portions 130b, 230b of the first active layer 130 and the second active layer 230 can be exposed from the gate insulating films 140, 240.

In addition, the gate insulating film 140, 240 can be disposed over the entirety of the first active layer 130 and the second active layer 230, or the gate insulating film 140, 240 can be formed integrally. The gate insulating film 140, 240 can include at least one of silicon oxide, silicon nitride, and metal oxide and can have a single film structure or a multilayer film structure. Further, the gate insulating film 140, 240 protects the channel portion 130n, 230n.

Referring to FIG. 1, the first gate electrode 150 and the second gate electrode 250 are disposed on the gate insulating film 140, 240. As shown, the first gate electrode 150 and the second gate electrode 250 overlap with the channel portions 130n, 230n of the first active layer 130 and the second active layer 230.

In addition, the first gate the electrode 150 and the second gate electrode 250 are made of an aluminum series metal such as aluminum Al or an aluminum alloy, a silver series metal such as silver (Ag) or a silver alloy, a copper series metal such as copper (Cu) or a copper alloy, molybdenum(Mo) series metal such as molybdenum (Mo) or a molybdenum alloy, chromium (Cr), tantalum (Ta), neodymium (Nd), and titanium (Ti) may be included. The first gate electrode 150 and the second gate electrode 250 can also have a multilayer structure including at least two conductive films having different physical properties.

Referring to FIG. 1, an interlayer insulating film 160 is disposed on the first gate electrode 150 and the second gate electrode 250. In particular, the interlayer insulating film 160 is an insulating layer made of an insulating material and can be made of an organic material, an inorganic material, or a laminate of an organic material layer and an inorganic material layer. As shown, the interlayer insulating film 160 can also be disposed over the entire first thin film transistor TR11 and the second thin film transistor TR12.

Referring again to FIG. 1, a source electrode 171, 271 and a drain electrode 172, 272 are disposed on the interlayer insulating film 160. As shown in FIG. 1, the first thin film transistor TR11 and the second thin film transistor TR12 each include the source electrode 171, 271 and the drain electrode 172, 272.

In addition, the source electrode 171, 271 and the drain electrode 172, 272 are disposed on the gate insulating film 140, 240. In particular, the first gate electrode 150 and second gate electrode 250 can be disposed on the same layer as the source electrode 171, 271 and the drain electrode 172, 272. The first gate electrode 150 and second gate electrode 250 can also be made using the same or similar materials and process.

In addition, the source electrode 171, 271 and the drain electrode 172, 272 can include at least one of an aluminum series metal such as aluminum (Al) or an aluminum alloy, a silver series metal such as silver (Ag) or a silver alloy, a copper series metal such as copper (Cu) or a copper alloy, a molybdenum series metal such as molybdenum (Mo) or a molybdenum alloy, chromium (Cr), tantalum (Ta), neodymium (Nd), and titanium (Ti). Source electrode 171, 271 and drain electrode 172, 272 can also have a multilayer structure including at least two conductive films, each having different physical properties.

As shown in FIG. 1, the source electrodes 171, 271 and the drain electrodes 172, 272 are connected to the first active layer 130 and the second active layer 230 through contact holes. Specifically, the source electrodes 171, 271 and the drain electrodes 172, 272 are connected to the first active layer 130 and the second active layer 230 by contacting the first connecting portions 130a, 230a and the second connecting portions 130b, 230b.

In addition, the first active layer 130 can be disposed between the first light-blocking layer 115 and the first gate electrode 150, and the second active layer 230 can be disposed between the second light-blocking layer 215 and the second gate electrode 250. In FIG. 1, the first active layer 130 is illustrated as being disposed between the first light-blocking layer 115 and the first gate electrode 150, and the second active layer 230 is illustrated as being disposed between the second light-blocking layer 215 and the second gate electrode 250.

In addition, in an alternative embodiment, additional measures can be used to increase the release of hydrogen in the driving transistor. For example, dummy through holes can be formed in the driving transistor to increase the release of hydrogen, and additional dummy layers can be formed with the second material.

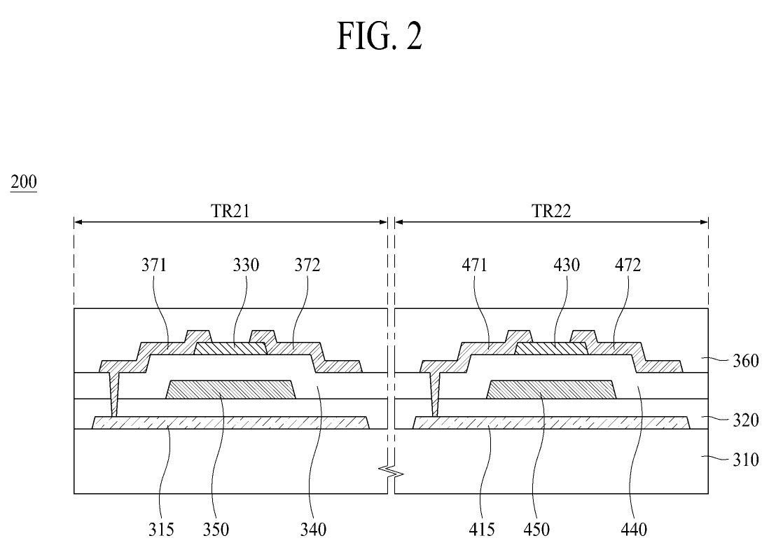

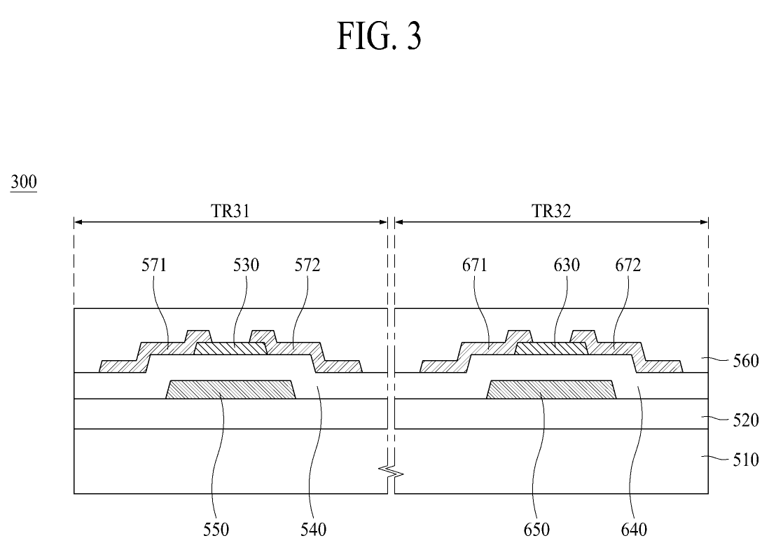

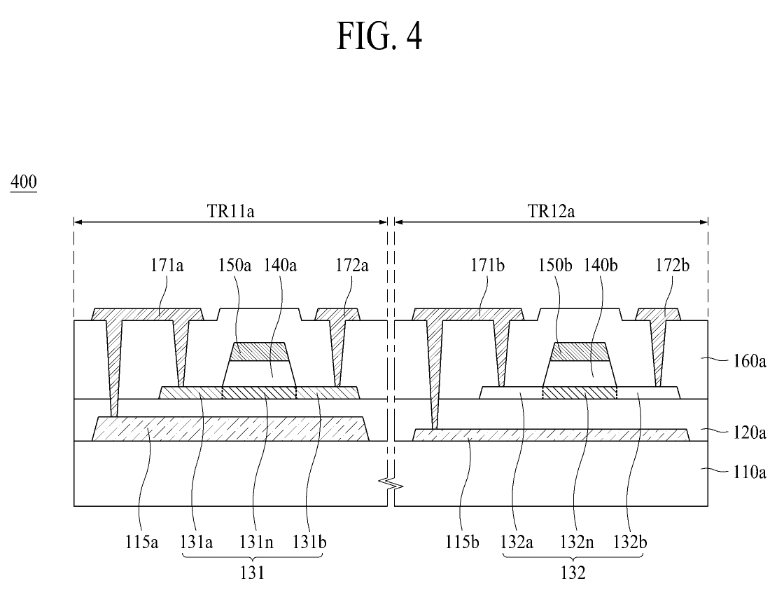

Next, FIG. 2 is a cross-sectional view of a thin film transistor substrate 200 , FIG. 3 is a cross-sectional view of a thin film transistor substrate 300, and FIG. 4 is a cross-sectional view of a thin film transistor substrate 400 according to other embodiments of the present disclosure.

As shown in FIG. 2, a first gate electrode 350 can be disposed between a first light-blocking layer 315 and a first active layer 330, and a second gate electrode 450 can be disposed between a second light-blocking layer 415 and a second active layer 430. Referring to FIG. 2, the thin film transistor substrate 200 according to one embodiment of the present disclosure includes a first thin film transistor TR21 and a second thin film transistor TR22 spaced apart from each other.

As shown in FIG. 2, the first thin film transistor TR21 includes the first active layer 330, the first gate electrode 350 that at least partially overlaps the first active layer 330, and the first light-blocking layer 315 that is disposed between a base substrate 310 and the first active layer 330 and overlaps the first active layer 330. In addition, the second thin film transistor TR22 includes the second active layer 430, the second gate electrode 450 that at least partially overlaps the second active layer 430, and the second light-blocking layer 415 that is disposed between the base substrate 310 and the second active layer 430 and overlaps the second active layer 430.

Also, FIG. 2 illustrates that the first gate electrode 350 can be disposed between the first light-blocking layer 315 and the first active layer 330, and the second gate electrode 450 can be disposed between the second light-blocking layer 415 and the second active layer 430. In addition, the first light-blocking layer 315 and the second light-blocking layer 415 are spaced apart from each other and disposed on the base substrate 310, and a buffer layer 320 is disposed on the first light-blocking layer 315 and the second light-blocking layer 415. Also, the first gate electrode 350 and the second gate electrode 450 are disposed on the buffer layer 320, and a gate insulating film 340, 440 is disposed on the first gate electrode 350 and the second gate electrode 450. In addition, the first active layer 330 and the second active layer 430 are disposed on the gate insulating film 440. As shown, a source electrode 371 and a drain electrode 372 are disposed on the first active layer 330, and a source electrode 471 and a drain electrode 472 are disposed on the second active layer 430. An interlayer insulating film 360 is also disposed on the source electrode 371, 471 and the drain electrode 372, 472.

The description of the base substrate 310, the first light-blocking layer 315, the second light-blocking layer 415, the buffer layer 320, the first gate electrode 350, the second gate electrode 450, the gate insulating film 340, 440, the first active layer 330, the second active layer 430, the source electrode 371, 471, the drain electrode 372, 472, and the interlayer insulating film 360 illustrated in FIG. 2 overlap with those of the base substrate 110, the first light-blocking layer 115, the second light-blocking layer 215, the buffer layer 120, the first gate electrode 150, the second gate electrode 250, the gate insulating film 140, 240, the first active layer 130, the second active layer 230, the source electrode 171, 271, the drain electrode 172, 272 and the interlayer insulating film 160 illustrated in FIG. 1. Compared to the thin film transistor substrate 100 of FIG. 1, the thin film transistor substrate 200 of FIG. 2 has the gate insulating film 340, 440 disposed over the entire upper surface of the buffer layer 320.

Referring to FIG. 3, a first gate electrode 550 and a second gate electrode 650 can be made of different materials, and the hydrogen concentration (at %) of a second active layer 630 can be higher than the hydrogen concentration (at %) of a first active layer 530. Also, the thin film transistor substrate 300 of FIG. 3 includes a first thin film transistor TR31 and a second thin film transistor TR32 that are spaced apart from each other.

In particular, the thin film transistor substrate 300 of FIG. 3 does not include the first light blocking layer 315 and the second light blocking layer 415 compared to the thin film transistor substrate 200 of FIG. 2. The description of the base substrate 510, the buffer layer 520, the gate insulating film 540, 640, the first active layer 530, the second active layer 630, the source electrode 571, 671, the drain electrode 572, 672, and the interlayer insulating film 560 illustrated in FIG. 3 overlaps with the description of the base substrate 310, the buffer layer 320, the gate insulating film 340, 440, the first active layer 330, the second active layer 430, the source electrode 371, 471, the drain electrode 372, 472, and the interlayer insulating film 360 illustrated in FIG. 2.

Referring to FIG. 3, the first gate electrode 550 and second gate electrode 650 is made of different materials. Specifically, the first gate electrode 550 includes a first metal material, and the second gate electrode 650 includes a second metal material. More specifically, the first metal material can be a metal material that captures hydrogen (H), and the second metal material can be a metal material that does not capture or emits hydrogen (H). That is, the first metal material can be more stably bonded to hydrogen than the second metal material. For example, the binding energy of the first metal material with hydrogen can be greater than the binding energy of the second metal material with hydrogen.

Descriptions of the first metal material and the second metal material overlap with the previous description. Further, the threshold voltage (Vth) of the first thin film transistor TR31 can be greater than the threshold voltage (Vth) of the second thin film transistor TR32.

In addition, the hydrogen concentration (at %) of the second active layer 630 can be higher than the hydrogen concentration of the first active layer 530. For example, the first active layer 530 can have a hydrogen concentration greater than or equal to 1x10¹⁰ and less than 1x10¹⁷ atomic % (at %) based on the entirety of the first active layer 530, and the second active layer 630 can have a hydrogen concentration of 1x10¹⁷ to 1x10²¹ atomic % (at %) based on the entirety of the second active layer 630. Further, the carrier mobility of the second active layer 630 can be greater than the carrier mobility of the first active layer 530.

Referring to FIG. 4, the thin film transistor substrate 400 can include a third thin film transistor TR11a on a base substrate 110a and a fourth thin film transistor TR12a spaced apart from the third thin film transistor TR11a. The base substrate 110a illustrated in FIG. 4 corresponds to the base substrate 110 illustrated in FIG. 1.

In addition, the third thin film transistor TR11a includes a first active layer 131, a first gate electrode 150a that at least partially overlaps the first active layer 131, and a first light-blocking layer 115a that is disposed between the base substrate 110a and the first active layer 131 and overlaps the first active layer 131. As shown, the fourth thin film transistor TR12a includes a second active layer 132, a second gate electrode 150b that at least partially overlaps the second active layer 132, and a second light-blocking layer 115b that is disposed between the base substrate 110a and the second active layer 132 and overlaps the second active layer 132.

In addition, the first active layer 131 includes a first oxide semiconductor material, and the second active layer 132 includes a second oxide semiconductor material. For example, the first oxide semiconductor material can be a high-mobility material, and the second oxide semiconductor material can be a low-mobility material. Also, the carrier mobility of the first oxide semiconductor material can be greater than the carrier mobility of the second oxide semiconductor material.

Further, as shown in FIG. 4, the thickness of the first light-blocking layer 115a can be greater than the thickness of the second light-blocking layer 115b. Also, the first light-blocking layer 115a and the second light-blocking layer 115b can each include a first metal material. For example, the first metal material may include any one of titanium (Ti), molybdenum titanium alloy (MoTi), lithium (Li), hafnium (Hf), lutetium (Lu), tantalum (Ta), magnesium (Mg), vanadium (V), rubinium (Rb), scandium (Sc), strontium (Sr), yttrium (Y), zirconium (Zr), niobium (Nb), cesium (Cs), barium (Ba), and lanthanum (La).

Also, the first light-blocking layer 115a and the second light-blocking layer 115b can stably bind to hydrogen. For example, the first metal material can be a metal material that captures hydrogen (H). Specifically, when the thickness of the first light-blocking layer 115a is greater than the thickness of the second light-blocking layer 115b, the first light-blocking layer 115a has more space for capturing hydrogen inside than the second light-blocking layer 115b, so the first light-blocking layer 115a can bind to or capture a larger amount of hydrogen than the second light-blocking layer 115b.

Even if the first oxide semiconductor material of the first active layer 131 has a higher carrier mobility than the second oxide semiconductor material of the second active layer 132, the thickness of the first light-blocking layer 115a is greater than the thickness of the second light-blocking layer 115b, so that the hydrogen concentration of the first active layer 131 can be controlled. That is, even if the first oxide semiconductor material of the first active layer 131 has a higher carrier mobility than the second oxide semiconductor material of the second active layer 132, the first active layer 131 can have a hydrogen concentration greater than or equal to 1x10¹⁰ and less than 1x10¹⁷ atomic % (at %) based on the entirety of the first active layer 131, and the second active layer 132 can have a hydrogen concentration greater than or equal to 1x10¹⁰ and less than 1x10¹⁷ atomic % (at %) based on the entirety of the second active layer 132.

In addition, the third thin film transistor TR11a and the fourth thin film transistor TR12a of the thin film transistor substrate 400 according to one embodiment of the present disclosure can each be included in the gate driver 321 or can be switching thin film transistors. For example, even if the first oxide semiconductor material of the first active layer 131 of the third thin film transistor TR11a has high carrier mobility, the hydrogen concentration in the first active layer 131 can be maintained at 1x10¹⁰ or more and less than 1x10¹⁷ atomic % (at %) by controlling the thickness of the first light-blocking layer 115a. As a result, the third thin film transistor TR11a can implement a short channel, and the current capacity of the third thin film transistor TR11a can be increased.

For example, even if the second oxide semiconductor material of the second active layer 132 of the fourth thin film transistor TR12a has a low carrier mobility, the hydrogen concentration in the second active layer 132 can be maintained at 1x10¹⁰ or more and less than 1x10¹⁷ atomic % (at %) by controlling the thickness of the second light-blocking layer 115b. As a result, the fourth thin film transistor TR12a can implement a short channel, and the current capacity of the fourth thin film transistor TR12a can be increased.

Next, FIG. 5 is a schematic diagram of a display device 1000 according to an embodiment of the present disclosure. As shown, the display device 1000 can include a display panel 311, a gate driver 321, a data driver 331, and a control unit 341.

As shown in FIG. 5, the display panel 311 includes gate lines (GL) and data lines (DL), and pixels (P) disposed at intersections of the gate lines (GL) and data lines (DL). An image is displayed by driving the pixels (P), and the gate lines (GL), data lines (DL), and pixels (P) can be disposed on the base substrate 110.

Further, the control unit 341 controls the gate driver 321 and the data driver 331. In particular, the control unit 341 outputs a gate control signal (GCS) for controlling the gate driver 321 and a data control signal (DCS) for controlling the data driver 331 by using a signal supplied from an external system. In addition, the control unit 341 samples input image data input from an external system, rearranges it, and supplies redisposed digital image data (RGB) to the data driver 331. The gate control signal (GCS) includes a gate start pulse (GSP), a gate shift clock (GSC), a gate output enable signal (GOE), a start signal (Vst), and a gate clock (GCLK). In addition, the gate control signal (GCS) can include control signals for controlling the shift register.

Further, the data control signals (DCS) include a source start pulse (SSP), a source shift clock signal (SSC), a source output enable signal (SOE), and a polarity control signal (POL). The data driver 331 supplies data voltage to the data lines (DL) of the display panel 311. Specifically, the data driver 331 converts image data (RGB) input from the control unit 341 into analog data voltage and supplies the data voltage to data lines (DL).

Also, the gate driver 321 can be mounted on the display panel 311. Also, the gate driver 321directly mounted on the display panel 311 is called a gate in panel (GIP) structure. Specifically, in the GIP structure, the gate driver 321 can be disposed on the base substrate 110.

In addition, the display device 1000 can include the thin film transistor substrate 100, 200, 300, 400 described above. Further, the gate driver 321 can include the thin film transistor substrate 100, 200, 300, 400 described above. The gate driver 321 can also include a shift register 351.

In particular, the shift register 351 sequentially supplies gate pulses to gate lines (GL) for one frame using a start signal and gate clock transmitted from the control unit 341. Here, one frame refers to a period during which one image is output through the display panel 311. The gate pulse has a turn-on voltage capable of turning on a switching element thin film transistor disposed in a pixel (P).

In addition, the shift register 351 supplies a gate off signal capable of turning off the switching element to the gate line (GL) during the remaining period during which the gate pulse is not supplied during one frame. Hereinafter, the gate pulse and the gate off signal are collectively referred to as a scan signal (SS or Scan). The shift register 351 can include the thin film transistor substrate 100, 200, 300, 400 described above.

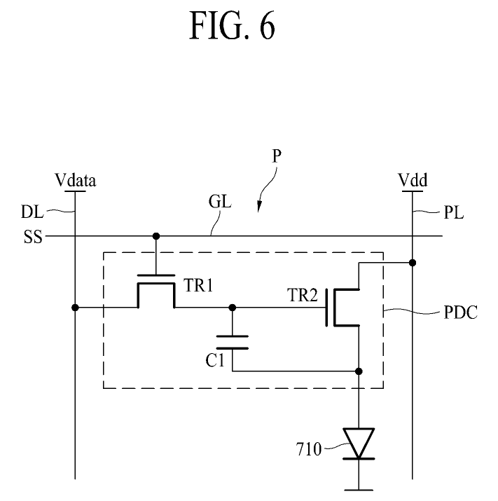

Next, FIG. 6 is a circuit diagram for one pixel (P) of FIG. 5. In particular, the circuit diagram of FIG. 6 is an equivalent circuit diagram for a pixel (P) of a display device 1000 including an organic light-emitting diode (OLED) as a display element 710. Referring to FIG. 6, a pixel (P) includes a display element 710 and a pixel driving circuit (PDC) that drives the display element 710. Specifically, the display device 1000 according to one embodiment of the present disclosure can include the pixel driving circuit (PDC) on the base substrate 110.

In addition, the pixel driving circuit (PDC) of FIG. 6 includes a first thin film transistor TR1 as a switching transistor and a second thin film transistor TR2 as a driving transistor. According to an embodiment of the present disclosure, the pixel driving circuit (PDC) includes a first thin film transistor TR11, TR21, TR31 according to an embodiment of the present disclosure as a switching transistor, and a second thin film transistor TR12, TR22, TR32 according to an embodiment of the present disclosure as a driving transistor. In addition, the pixel driving circuit (PDC) can include any one of the third thin film transistor TR11a and the fourth thin film transistor TR12a illustrated in FIG. 4 as a switching transistor.

In addition, the first thin film transistor TR1 is connected to the gate line (GL) and the data line (DL), and is turned on or off by the scan signal (SS) supplied through the gate line (GL). The data line (DL) provides a data voltage (Vdata) to the pixel driver circuit (PDC), and the first thin film transistor TR1 controls the application of the data voltage (Vdata). The driving power line (PL) provides a driving voltage (Vdd) to the display element 710, and the first thin film transistor TR1 controls the driving voltage (Vdd). The driving voltage (Vdd) is a pixel driving voltage for driving an organic light-emitting diode (OLED), which is the display element 710.

When the first thin film transistor TR1 is turned on by a scan signal (SS) applied through the gate line (GL) from the gate driver 321, the data voltage (Vdata) supplied through the data line (DL) is supplied to the gate electrode of the second thin film transistor TR2 connected to the display element 710. The data voltage (Vdata) is charged in the storage capacitor (C1) formed between the gate electrode and the source electrode of the second thin film transistor TR2. The amount of current supplied to the organic light-emitting diode (OLED), which is a display element 710, through the second thin film transistor TR2 is controlled according to the data voltage (Vdata), and accordingly, the gradation of light output from the display element 710 can be controlled.

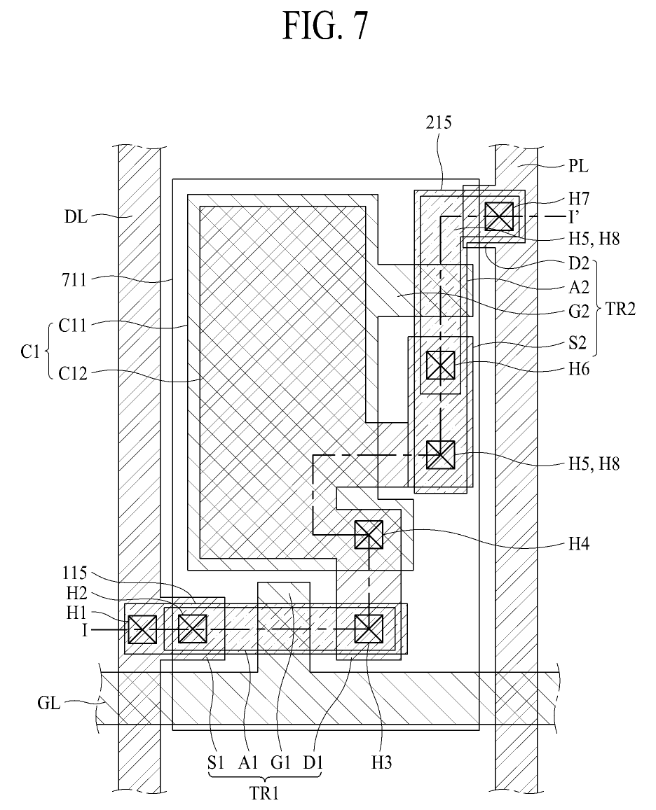

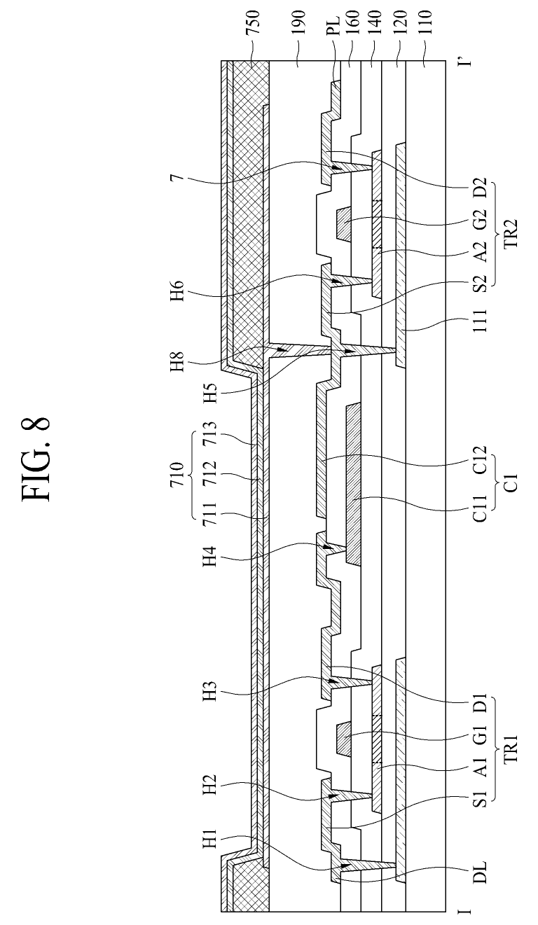

Next, FIG. 7 is a plan view of the pixel of FIG. 6, and FIG. 8 is a cross-sectional view taken along line I-I’ of FIG. 7. Referring to FIGS. 7 and 8, the first thin film transistor TR1 and the second thin film transistor TR2 are disposed on the base substrate 110. The base substrate 110 can be made of glass or plastic. As the base substrate 110, a plastic having flexible properties, for example, polyimide (PI), can be used.

As shown, the first light-blocking layer 115 and the second light-blocking layer 215 are disposed on the base substrate 110. In particular, the first light-blocking layer 115 and the second light-blocking layer 215 have light-blocking properties. The first light-blocking layer 115 and the second light-blocking layer 215 can thus block light incident from the outside to protect the active layers (A1, A2).

In addition, as described above, the first light-blocking layer 115 can include a first metal material, and the second light-blocking layer 215 can include a second metal material. Also, a buffer layer 120 is disposed on the first light-blocking layer 115 and the second light-blocking layer 215. In more detail, the buffer layer 120 is made of an insulating material and protects the active layers (A1, A2) from moisture or oxygen flowing in from the outside.

Further, the active layer (A1) of the first thin film transistor TR1 and the active layer (A2) of the second thin film transistor TR2 are disposed on a buffer layer 120. The active layers (A1, A2) can include, for example, an oxide semiconductor material and can have a multilayer structure made of an oxide semiconductor material.

In addition, the gate insulating film 140 is disposed on the active layer (A1, A2). Also, the gate insulating film 140 covers the upper surface of the active layer (A1, A2). A gate electrode (G1) of a first thin film transistor TR1 and a gate electrode (G2) of a second thin film transistor TR12 are disposed on a gate insulating film 140. In addition, a gate line (GL) can be disposed on the gate insulating film 140. The gate electrode (G1) of the first thin film transistor TR1 can extend from the gate line (GL) or can be a part of the gate line (GL).

Referring to FIGS. 7 and 8, a first capacitor electrode (CE1) of a storage capacitor (Cst) is formed on a gate insulating film 140. The first capacitor electrode (CE1) can be formed using the same or similar material as the gate electrodes (G1, G2) through the same or similar process. An interlayer insulating film 160 is disposed on the gate electrodes (G1, G2) and the first capacitor electrode (CE1).

In addition, a data line (DL) and a driving power line (PL) are disposed on an interlayer insulating film 160. In addition, a source electrode (S1) and a drain electrode (D1) of a first thin film transistor TR1 are disposed on the interlayer insulating film 160, and a source electrode (S2) and a drain electrode (D2) of a second thin film transistor TR2 are disposed.

Further, the source electrode (S1) of the first thin film transistor TR1 can be formed integrally with the data line (DL) and can have a structure extending from the data line (DL). The source electrode (S1) of the first thin film transistor TR1 can contact the first light-blocking layer 115 of the first thin film transistor TR1 through the first contact hole (H1). The source electrode (S1) of the first thin film transistor TR1 can contact the side of the active layer (A1) of the first thin film transistor TR1through the second contact hole (H2).

Further, the drain electrode (D1) of the first thin film transistor TR1 contacts the other side of the active layer (A1) of the first thin film transistor TR1 through the third contact hole (H3). In addition, the drain electrode (D1) of the first thin film transistor TR1 is connected to the first capacitor electrode (CE1) through the fourth contact hole (H4). As a result, the first capacitor electrode (CE1) can be connected to the first thin film transistor TR1

Also, the drain electrode (D2) of the second thin film transistor TR2 may be formed integrally with the driving power line (PL) and may have a structure extending from the driving power line (PL). The drain electrode (D2) of the second thin film transistor TR2 can come into contact with the side of the active layer (A2) of the second thin film transistor TR2 through the seventh contact hole (H7).

In addition, the source electrode (S2) of the second thin film transistor TR2 contacts the other side of the active layer (A2) of the second thin film transistor TR2 through the sixth contact hole (H6). In addition, the source electrode (S2) of the second thin film transistor TR2 is connected to the second light-blocking layer 215 through the fifth contact hole (H5). The same voltage as the source electrode (S2) of the second thin film transistor TR2 can be applied to the second light-blocking layer 215 overlapping the second thin film transistor TR2. The source electrode (S2) of the second thin film transistor TR2 can extend onto the interlayer insulating film 160 to form a second capacitor electrode (CE2) of the storage capacitor (Cst). Further, a first capacitor electrode (CE1) and a second capacitor electrode (CE2) may overlap to form a storage capacitor (Cst).

Referring to FIGS. 7 and 8, a planarization layer 190 is disposed on the data line (DL), the driving power line (PL), the source electrodes (S1, S2), the drain electrodes (D1, D2), and the second capacitor electrode (CE2). In particular, the planarization layer 190 planarizes the upper portions of the first thin film transistor TR1 and the second thin film transistor TR2, and protects the first thin film transistor TR1 and the second thin film transistor TR2. The planarization layer 190 thus functions as a protective layer.

Also, a first electrode 711 of a display element 710 is placed on a planarization layer 190. As shown, the first electrode 711 of the display element 710 contacts a second capacitor electrode (CE2) through an eighth contact hole (H8) formed in the planarization layer 180. As a result, the first electrode 711 of the display element 710 can be connected to a source electrode (S2) of a second thin film transistor TR2. A bank layer 750 is disposed at the edge of the first electrode 711. The bank layer 750 defines a light-emitting area of the display element 710.

As shown, an organic light-emitting layer 712 is disposed on a first electrode 711, and a second electrode 713 is disposed on the organic light-emitting layer 712. Accordingly, a display element 710 is completed. The display element 710 illustrated in FIG. 8 is an organic light-emitting diode OLED. Therefore, a display device 1000 according to an embodiment of the present disclosure is an organic light-emitting display device.

A pixel driving circuit (PDC) according to another embodiment of the present disclosure can be formed in various structures other than the structures described above. The PDC can include, for example, three or more thin film transistors.

In addition, the following advantageous effects can be obtained according to embodiments of the present disclosure. In particular, a thin film transistor substrate according to one embodiment of the present disclosure can improve device characteristics by including a first thin film transistor and a second thin film transistor having different light-blocking layers.

Also, a thin film transistor substrate according to one embodiment of the present disclosure can control the hydrogen concentration of an active layer by including a first thin film transistor and a second thin film transistor having different light-blocking layers. A thin film transistor substrate includes a first thin film transistor and a second thin film transistor having different light-blocking layers, thereby controlling threshold voltages differently to increase the current capacity of a switching transistor and improve the driving stability of a driving transistor.

Features of various embodiments of the present disclosure can be partially or overall coupled to or combined with each other, and can be variously inter-operated with each other and driven technically as those skilled in the art can sufficiently understand. Embodiments of the present disclosure can be carried out independently from each other, or can be carried out together in co-dependent relationship.

It will be apparent to those skilled in the art that the present disclosure described above is not limited by the above-described embodiments and the accompanying drawings and that various substitutions, modifications and variations can be made in the present disclosure without departing from the technical idea or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A thin film transistor substrate comprising:
a first switching thin film transistor on a base substrate; and
a second driving thin film transistor on the base substrate and spaced apart from the first switching thin film transistor,
wherein the first switching thin film transistor includes:
a first active layer;
a first gate electrode at least partially overlapping the first active layer; and
a first light-blocking layer disposed between the base substrate and the first active layer and overlapping the first active layer,
wherein the second driving thin film transistor includes:
a second active layer;
a second gate electrode at least partially overlapping the second active layer; and
a second light-blocking layer disposed between the base substrate and the second active layer and overlapping the second active layer,
wherein the first light-blocking layer and the second light-blocking layer are made of different materials, and
wherein a hydrogen concentration of the second active layer is higher than a hydrogen concentration of the first active layer.

2. The thin film transistor substrate of claim 1, wherein the first active layer has a hydrogen concentration greater than or equal to 1x10¹⁰ atomic % and less than 1x10¹⁷ atomic % based on an entirety of the first active layer, and
wherein the second active layer has a hydrogen concentration of 1x10¹⁷ atomic % to 1x10²¹ atomic % based on an entirety of the second active layer.

3. The thin film transistor substrate of claim 1, wherein a carrier mobility of the second active layer is greater than a carrier mobility of the first active layer, and
wherein a threshold voltage of the first switching thin film transistor is greater than a threshold voltage of the second driving thin film transistor.

4. The thin film transistor substrate of claim 1, wherein the first light-blocking layer includes a first metal material,
wherein the second light-blocking layer includes a second metal material, and
wherein a binding energy of the first metal material with hydrogen is greater than a binding energy of the second metal material with hydrogen.

5. The thin film transistor substrate of claim 4, wherein the first metal material includes any one of titanium, molybdenum titanium alloy, lithium, hafnium, lutetium, tantalum, magnesium, vanadium, rubinium, scandium, strontium, yttrium, zirconium, niobium, cesium, barium, and lanthanum, and
wherein the second metal material includes any one of molybdenum, copper, tungsten, cobalt, zinc, gallium, silver, cadmium, indium, tin, iridium, platinum, and gold.

6. The thin film transistor substrate of claim 1, wherein the first active layer is disposed between the first light-blocking layer and the first gate electrode, and
wherein the second active layer is disposed between the second light-blocking layer and the second gate electrode.

7. The thin film transistor substrate of claim 1, wherein the first gate electrode is disposed between the first light-blocking layer and the first active layer, and
wherein the second gate electrode is disposed between the second light-blocking layer and the second active layer.

8. A thin film transistor substrate comprising:
a first switching thin film transistor on a base substrate; and
a second driving thin film transistor on the base substrate and spaced apart from the first thin film transistor,
wherein the first switching thin film transistor comprises:
a first active layer; and
a first gate electrode disposed between the base substrate and the first active layer and at least partially overlapping the first active layer,
wherein the second driving thin film transistor comprises:
a second active layer; and
a second gate electrode disposed between the base substrate and the second active layer and at least partially overlapping the second active layer,
wherein the first gate electrode and the second gate electrode are made of different materials, and
wherein a hydrogen concentration of the second active layer is higher than a hydrogen concentration of the first active layer.

9. The thin film transistor substrate of claim 8, wherein the first active layer has a hydrogen concentration greater than or equal to 1x10¹⁰ atomic % and less than 1x10¹⁷ atomic % based on the entirety of the first active layer, and
wherein the second active layer has a hydrogen concentration of 1x10¹⁷ atomic % to 1x10²¹ atomic % based on the entirety of the second active layer.

10. The thin film transistor substrate of claim 8, wherein a carrier mobility of the second active layer is greater than a carrier mobility of the first active layer, and
wherein a threshold voltage of the first switching thin film transistor is greater than a threshold voltage of the second driving thin film transistor.

11. The thin film transistor substrate of claim 8, wherein the first gate electrode includes a first metal material,
wherein the second gate electrode includes a second metal material, and
wherein a binding energy of the first metal material with hydrogen is greater than a binding energy of the second metal material with hydrogen.

12. The thin film transistor substrate of claim 11, wherein the first metal material includes any one of titanium, molybdenum titanium alloy, lithium, hafnium, lutetium, tantalum, magnesium, vanadium, rubinium, scandium, strontium, yttrium, zirconium, niobium, cesium, barium, and lanthanum, and
wherein the second metal material includes any one of molybdenum, copper, tungsten, cobalt, zinc, gallium, silver, cadmium, indium, tin, iridium, platinum, and gold.

13. A thin film transistor substrate comprising:
a first switching thin film transistor on a base substrate; and
a second driving thin film transistor spaced apart from the first switching thin film transistor,
wherein the first switching thin film transistor comprises:
a first active layer;
a first gate electrode at least partially overlapping the first active layer; and
a first light-blocking layer disposed between the base substrate and the first active layer and overlapping the first active layer,
wherein the second driving thin film transistor comprises:
a second active layer;
a second gate electrode at least partially overlapping the second active layer; and
a second light-blocking layer disposed between the base substrate and the second active layer and overlapping the second active layer,
wherein the first active layer comprises a first oxide semiconductor material, and the second active layer comprises a second oxide semiconductor material,
wherein a carrier mobility of the first oxide semiconductor material is greater than a carrier mobility of the second oxide semiconductor material, and
wherein a thickness of the first light-blocking layer is greater than a thickness of the second light-blocking layer.

14. The thin film transistor substrate of claim 13, wherein the first active layer has a hydrogen concentration greater than or equal to 1x10¹⁰ atomic % and less than 1x10¹⁷ atomic % based on the entirety of the first active layer, and
wherein the second active layer has a hydrogen concentration greater than or equal to 1x10¹⁰ atomic % and less than 1x10¹⁷ atomic % based on the entirety of the second active layer.

15. The thin film transistor substrate of claim 13, wherein the first light-blocking layer and the second light-blocking layer each include a first metal material, and
wherein the first metal material includes any one of titanium, a molybdenum titanium alloy, lithium, hafnium, lutetium, tantalum, magnesium, vanadium, rubinium, scandium, strontium, yttrium, zirconium, niobium, cesium, barium, and lanthanum.

16. A display device comprising:
a display panel;
a gate driver mounted on the display panel and including a first switching thin film transistor; and
a pixel driving circuit including the first switching thin film transistor and a second driving thin film transistor,
wherein the first switching thin film transistor includes:
a first active layer;
a first gate electrode at least partially overlapping the first active layer; and
a first light-blocking layer disposed between the base substrate and the first active layer and overlapping the first active layer,
wherein the second driving thin film transistor includes:
a second active layer;
a second gate electrode at least partially overlapping the second active layer; and
a second light-blocking layer disposed between the base substrate and the second active layer and overlapping the second active layer,
wherein the first light-blocking layer and the second light-blocking layer are made of different materials, and
wherein a hydrogen concentration of the second active layer is higher than a hydrogen concentration of the first active layer.

17. The display device of claim 16, wherein the first active layer comprises a first oxide semiconductor material, and the second active layer comprises a second oxide semiconductor material,
wherein a carrier mobility of the first oxide semiconductor material is greater than a carrier mobility of the second oxide semiconductor material.

18. The display device of claim 17, wherein the first light-blocking layer includes a first metal material,
wherein the second light-blocking layer includes a second metal material, and
wherein a binding energy of the first metal material with hydrogen is greater than a binding energy of the second metal material with hydrogen.

19. The display device of claim 16, wherein the first active layer has a hydrogen concentration greater than or equal to 1x10¹⁰ atomic % and less than 1x10¹⁷ atomic % based on an entirety of the first active layer, and
wherein the second active layer has a hydrogen concentration of 1x10¹⁷ atomic % to 1x10²¹ atomic % based on an entirety of the second active layer.

20. The display device of claim 16, wherein a carrier mobility of the second active layer is greater than a carrier mobility of the first active layer, and
wherein a threshold voltage of the first switching thin film transistor is greater than a threshold voltage of the second driving thin film transistor.
